(19) United States
(12) Patent Application Publication
(10) Pub. No.: US 2002/0146896 A1
(43) Pub. Date: Oct. 10, 2002

(54) Metallizaton methods using foils

(76) Inventor: Woo Sik Yoo, Palo Alto, CA (US)

Correspondence Address: SKJERVEN MORRILL LLP, 25 METRO DRIVE, SUITE 700, SAN JOSE, CA, 95110, US

(21) Appl. No.: 09/828,017

(22) Filed: Apr. 6, 2001

(51) Int. Cl. H01L 21/20

(52) U.S. Cl. 438/584; 438/687

(57) ABSTRACT

A system and method for filling a plurality of closely-spaced apart recesses to form a high-density pattern in the surface of a substrate. The metallization system and process includes providing a substrate, which includes a first surface defining a plurality of recesses; overlaying a resistive foil on the first surface; and subjecting the substrate to a pressure to cause said resistive foil to enter said plurality of recesses.

### BACKGROUND

1. Field of Invention

The present invention relates to a method for forming a layer of an electrically conductive material on a substrate surface; and, more particularly, to a method of filling a plurality of closely-spaced apart recesses in the surface of the substrate.

2. Related Art

In the semiconductor industry, metal films can be formed as part of high-density metallization processing, which employ “damascene” (or “in-laid”) technology, of particular utility in integrated circuit semiconductor device and circuit board manufacture. The metal films can be used in semiconductor manufacturing technology, to form electrically conductive contacts to active, as well as passive, device regions or components formed in or on a semi-conductor substrate, as well as for filling via holes, inter-level metallization, and interconnection routing patterns for wiring together the components and/or regions.

Typically, metallization patterns are formed in a damascene processing sequence to create, for example, back-end contacts, vias, interconnections, routing, and the like, in a semi-conductor device formed in or on a semi-conductor wafer substrate. The pattern of recesses, may include grooves, trenches, holes, and the like, formed, for example, by etching in the surface of a dielectric layer deposited or otherwise formed over the semiconductor substrate. A suitably conductive metal layer is deposited over the etched recesses as a blanket layer of excess thickness, so as to overfill the recesses and cover the exposed upper surface of the dielectric layer. The excess thickness of the metal layer over the surface of the dielectric layer is removed using a chemical-mechanical polishing (CMP) process, including moving the wafer while urging the wafer surface into contact with a facing surface of a polishing pad and providing a slurry, including abrasive particles, in the area of contact. As a result of polishing, the portions of the metal layer overlying the surface of the dielectric layer are substantially completely removed, while the metal portions remain in the recesses with their exposed upper surfaces substantially co-planer with the surface of the dielectric layer.

Unfortunately, a problem associated with damascene processing of metallic materials arises from the phenomena of increased rates of erosion by CMP of high-density conductor patterns, such as patterns where the surface coverage by the layer of electrically conductive material forming the pattern is above 80% of the available surface area. Such increased erosion rates of regions of high-density metallization patterns by CMP also results in greater erosion of the dielectric layer portions intermediate the metallization features. As a consequence, non-planarity can occur across the surface of a wafer substrate. Moreover, typical methods for forming high-density in-laid metallization patterns by a damascene technique can include reduced electrical conductivity of the metallization features and reduce dielectric isolation resulting in degradation of device properties.

### SUMMARY

The present invention provides a system and method for filling a plurality of closely-spaced apart recesses forming a high-density pattern in the surface of the substrate. As a result, the exposed upper surface of the layer is substantially co-planer with non-recessed areas of the substrate surface. The method of the present invention also increases manufacturing through-put, and improves product quality.

In one aspect, a method of metallization is provided which includes providing a substrate, which includes a first surface defining a plurality of recesses; overlaying a resistive foil on the first surface; and subjecting the substrate to a pressure to cause said resistive foil to enter said plurality of recesses.

In another aspect, a system is provided for metallizing a substrate. The system includes a process chamber, which defines a cavity configured to receive a substrate. The substrate can have a plurality of recesses and may include a foil disposed on a surface thereof. The system also includes a pressurizing device for applying a pressure to the substrate. The pressure can cause the foil to move into each of the plurality of recesses.

These and other features and advantages of the present invention will be more readily apparent from the detailed description of the embodiments set forth below taken in conjunction with the accompanying drawings.

### BRIEF DESCRIPTION OF THE FIGURES

The present invention may be better understood, and it's numerous objects, features, and advantages made apparent to those skilled in the art by referencing the accompanying drawings.

FIG. 1 is a simplified illustration of a processing chamber including a pressurizing device in accordance with the present invention;

FIG. 2 is a simplified illustration of a portion of a substrate in accordance with the present invention;

FIGS. 3A and 3B are simplified illustrations of an embodiment of the pressurizing device of FIG. 1;

FIG. 4 is a simplified illustration of another embodiment of a pressurizing device of FIG. 1;

FIG. 5 is a simplified illustration of an embodiment of the present invention;

FIG. 6 is a simplified illustration of an embodiment of the present invention; and

FIG. 7 is a flow chart of a process in accordance with the present invention.

Embodiments of the present invention will be described with reference to the aforementioned figures. These figures have been simplified for ease of describing and understanding the embodiments. The use of the same reference symbols in different drawings indicates similar or identical items.

### DETAILED DESCRIPTION

The present invention will be discussed primarily in terms of selectively overlaying a metal film on a surface of a substrate, including a plurality of recesses. The plurality of recesses can include grooves, trenches, holes, and the like, formed, for example, by etching in the surface of a dielectric layer deposited or otherwise formed over the semiconductor substrate. It should be understood that that the overlaying process is not limited to any one type of surface but is applicable to metallizing any surface.

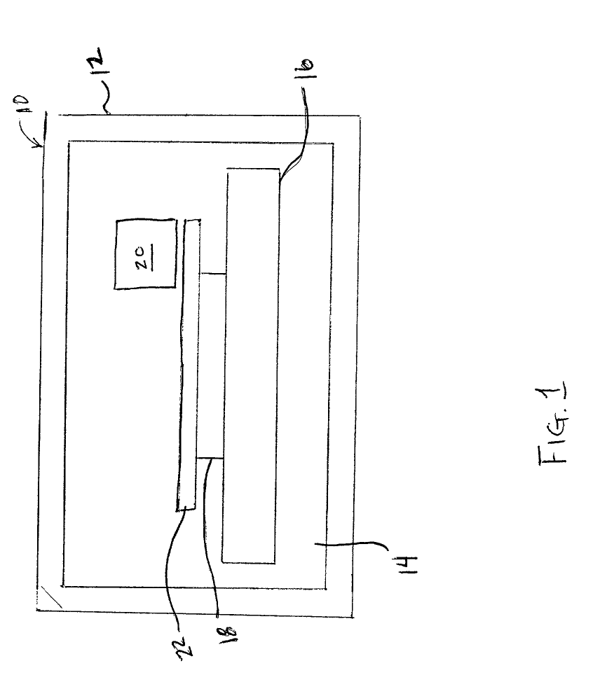

FIG. 1 is a simplified cross-sectional view of one embodiment of a processing chamber 10 in accordance with an embodiment of the present invention. Processing chamber 10 includes a housing 12, which defines an enclosed space 14. Housed within space 14 can be susceptor 16, including substrate support standoffs 18 (hereinafter “standoffs 18”), and a pressurizing device 20, embodiments of which are described in greater detail below. It should be understood that processing chamber 10 includes heating, insulatory and other structural components, the use of which are well known to those of ordinary skill in the art, for the proper operation of the processing chamber.

Externally, housing 12 may be metallic, preferably made of aluminum, stainless steel, or similar metal. Housing 12 has an opening (not shown) provided on a face of housing 12, which is configured to receive a substrate loader (not shown), such as a robotic arm. The opening allows for the loading and unloading of substrates from housing 12 before and after processing. The opening may be a relatively small opening, but with a width large enough to accommodate substrates, for example substrate 22. The relatively small opening size can help to reduce radiation heat loss from space 14. The small opening size keeps down the number of particles entering enclosed space 14 and allows for easier maintenance of the isothermal temperature environment.

To conduct a process, housing 12 is capable of being pressurized. For example, housing 12, can be made to withstand internal pressures of about 0.001 Torr to 10⁵ Torr, preferably between about 0.1 Torr and about 7600 Torr.

Susceptor 16, mounted within internal space 14 of housing 12, includes a platen that is fabricated of aluminum or other thermally conductive material with a top surface having a generally circular shape for supporting a semiconductor wafer within processing chamber 10. Typically, susceptor 16 includes a shaft, which is coupled to the bottom of the platen and supports the platen in processing chamber 10. A heating element can be mounted in or under the platen and arranged to be in thermally conductive contact with the surface of the platen such that substrate 22 supported by the platen can be heated during processing. Susceptor 16 includes standoffs 18 positioned on the surface of the platen, which can support substrate 22 during processing. Standoffs 18 may be any high temperature resistant material, such as quartz. Standoffs 18 may have a height of between about 50 μm and about 20 mm.

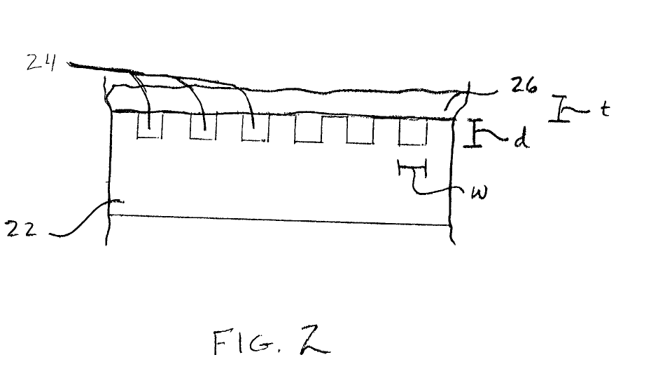

FIG. 2 is an enlarged view of a portion of substrate 22 in accordance with the present invention. In one embodiment, substrate 22 includes plurality of recesses 24, which provide electrical contact areas, vias, interlevel metallization, and interconnection routing. Recesses 24 can have a depth d between about 0.05 μm to about 0.10 mm and a width w between about 0.05 μm to about 0.10 mm, or a diameter of between about 0.05 μm and 0.10 mm. In some embodiments, recesses 24 are actual holes that can extend through substrate 22. Suitable substrates 22 can include inorganic and organic substances, such as glass, ceramics, porcelain, resins and the like.

FIG. 2 is a simplified illustration showing foil 26 overlaid onto substrate 22 as a self-supporting thin sheet. Thin metal foils are of use in various well-known applications. Most foils are manufactured by a mechanical process involving extrusion and pressing of metal sheets. Very thin metal foils may be fabricated using a vacuum vapor deposition. In such a process, a metal is vaporized and subsequently condensed onto a solid substrate to form a thin foil on the substrate. In another known process, a thin unbacked metal foil may be formed by a process, which includes depositing a layer of metal onto one side of a soluble substrate film so as to form a layer of metal foil thereon, and subsequently dissolving the film in a suitable solvent so as to leave the deposited layer of metal as an unbacked foil sheet. In one embodiment, foil 26 can have a thickness t up to about 1000 μm. Foil 26 can be made from any suitably conductive material, such as gold, aluminum, nickel, cobalt, silver, tungsten, titanium, tantalum, copper and alloys thereof.

Once fabricated, foil 26 can be manually transferred to a suitable supporting structure, such as substrate 22. When transferred to substrate 22, foil 26 fits loosely over the substrate surface. In most cases, foil 26 can be tightened before the metallization process occurs. In some cases, the application of heat from susceptor 16 (FIG. 1) is sufficient to tighten foil 26 on the surface of substrate 22.

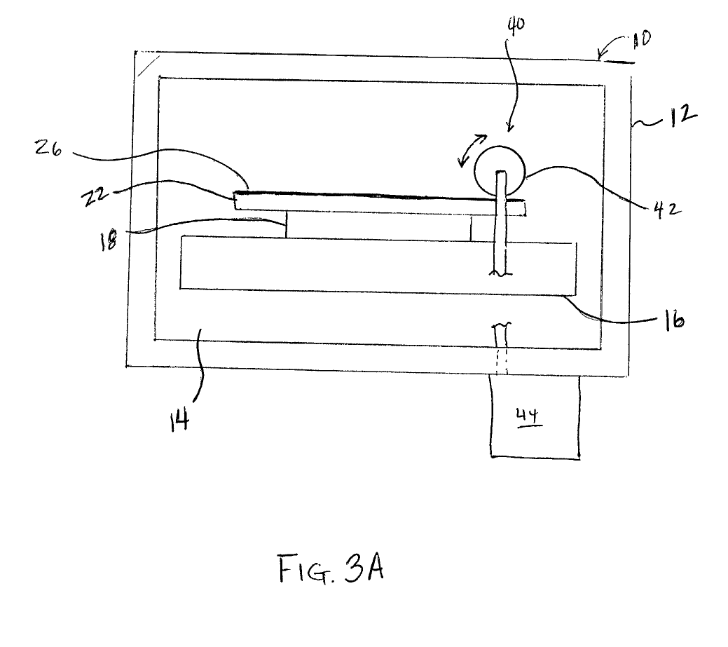

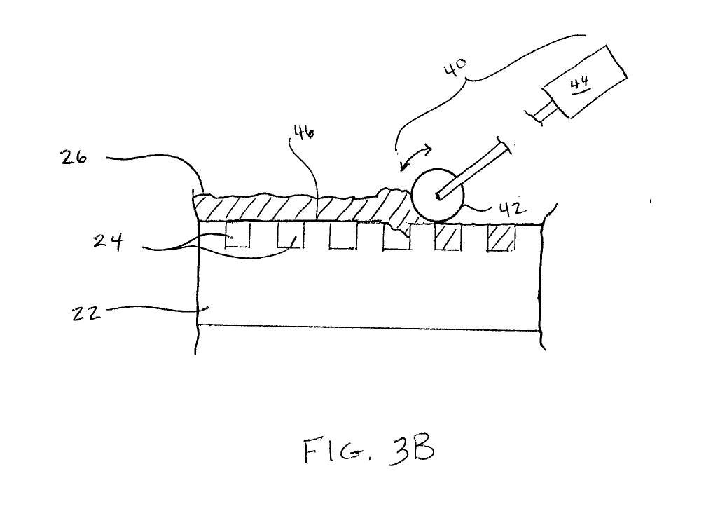

FIG. 3A is a simplified illustration of an embodiment of pressurizing device 20 (FIG. 1). In this embodiment, pressurizing device 20 includes a roller assembly 40, which may be used to provide the metallization of substrate 22. Roller assembly 40 can include a roller 42 and an actuator 44. Roller 42 can be, for example, a spherically or cylindrically shaped device used to provide pressure to a surface of substrate 22. Roller 42 can be heated to a temperature between about 100° C. and about 800° C.

In this embodiment, actuator 44 provides a conventional means for making roller assembly 40 operable to roll over substrate 22. Actuator 44 may be configured to move roller 42 in a continuous or a back and forth, rolling motion across substrate 22. One of ordinary skill in the art should recognize that actuator 44 may include, but is not limited to, conventional drivers and motion translation mechanisms, such as linear motors, stepper motors, hydraulic drives, and the like, and gears, pulleys, chains, linkages, and the like.

FIG. 3B, is a simplified illustration of roller assembly 40 in operation. After foil 26 has been applied to surface 46 of substrate 22, actuator 44 causes roller 42 to move over foil 26 and substrate surface 46. The pressure imparted to surface 46 from roller 42, causes foil 26 to be forced into recesses 24 until recesses 24 are filled with the desired amount of foil 26. The amount of pressure needed may vary, depending on the type of foil 260. Typically, recesses 24 are filled until the foil material in each recess 24 is substantially co-planer with substrate surface 46.

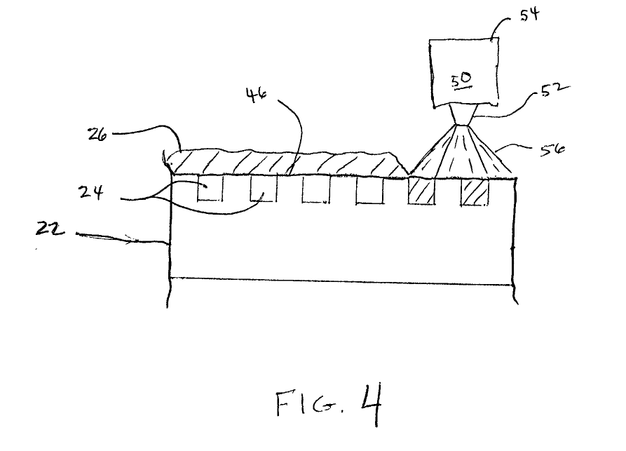

FIG. 4 is a simplified illustration of another embodiment of pressurizing device 20 (FIG. 1) in accordance with the present invention. In this embodiment, pressurizing device 20 includes a pressure applicator 50. Pressure applicator 50 can include a nozzle 52 or similarly performing device coupled to a reservoir 54. A fluid held in reservoir 54, either a liquid or a gas, is emitted from nozzle 52 as a stream 56, which impinges on the foil covered surface 46 of substrate 22. The fluid pressure causes foil 26 to enter recesses 24 to fill recesses 24. The amount of pressure forced upon foil 26 and substrate surface 46 can vary depending on, for example, the type of foil 26 being used, the depth of recesses 24 and the desired rate at which the processes is to proceed. For example, for a gold metal foil having a thickness of about 0.10 μm, the pressure impinging on substrate surface 46 can range from between about 0.001 Torr to 10⁵ Torr, preferably between about 0.1 Torr and about 7600 Torr. Typically, recesses 24 are filled until the foil material filling each recess 24 is substantially co-planer with substrate surface 46.

Although, the embodiment of FIG. 4 shows pressure applicator 50 impinging on only a portion of substrate 22, one of ordinary skill should understand that any amount of the substrate surface 46 of substrate 22, including the entire substrate surface 46 can be simultaneously subjected to the pressure from pressurizing device 50.

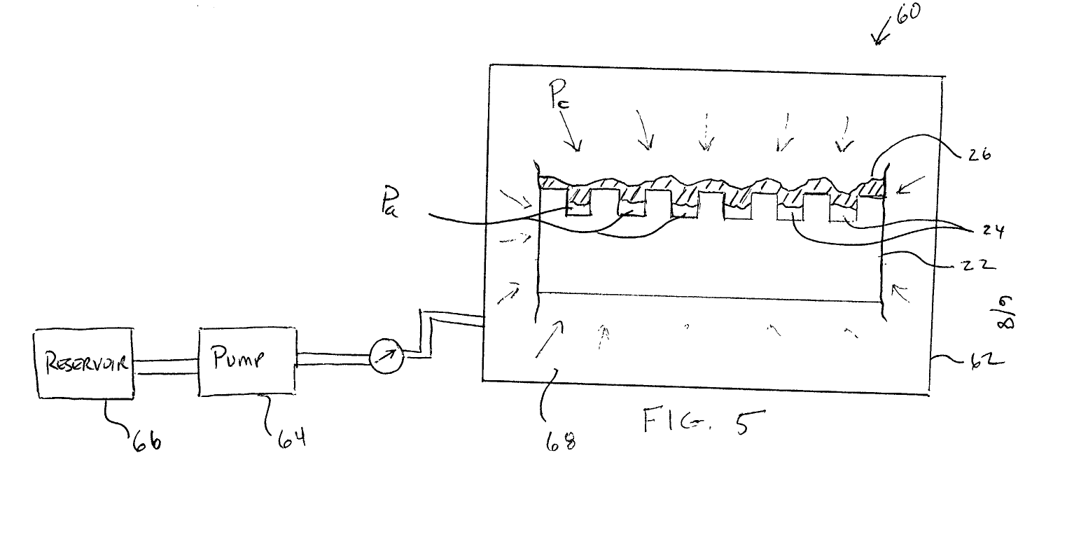

FIG. 5 is a simplified illustration of another embodiment of the present invention. In this embodiment, a process system 60 includes process chamber 62, pump 64 and fluid reservoir 66. Process chamber 60 defines an internal cavity 68, which can be completely pressurized. Accordingly, substrate 22 can be placed in cavity 68. In this embodiment, foil 26 can be tightened before the metallization process occurs to create a first pressure Pa within recesses 24. Pump 62 can be used to draw a gas from reservoir 66 to fill cavity 68 and place it under a chamber pressure Pc. Chamber pressure Pc can be made greater than pressure Pa in recesses 24 to cause foil 26 to be forced into recesses 24 to fill recesses 24. The amount of pressure Pc forced upon foil 26 and substrate surface 46 can vary depending on, for example, the type of foil 26 being used, the depth of recesses 24, pressure Pa and the desired rate at which the processes is to proceed. For example, chamber pressure Pc impinging on substrate 22 can range from between about 20 psig and 300 psig. Typically, recesses 24 are filled until the foil material filling each recess 24 is substantially co-planer with substrate surface 46.

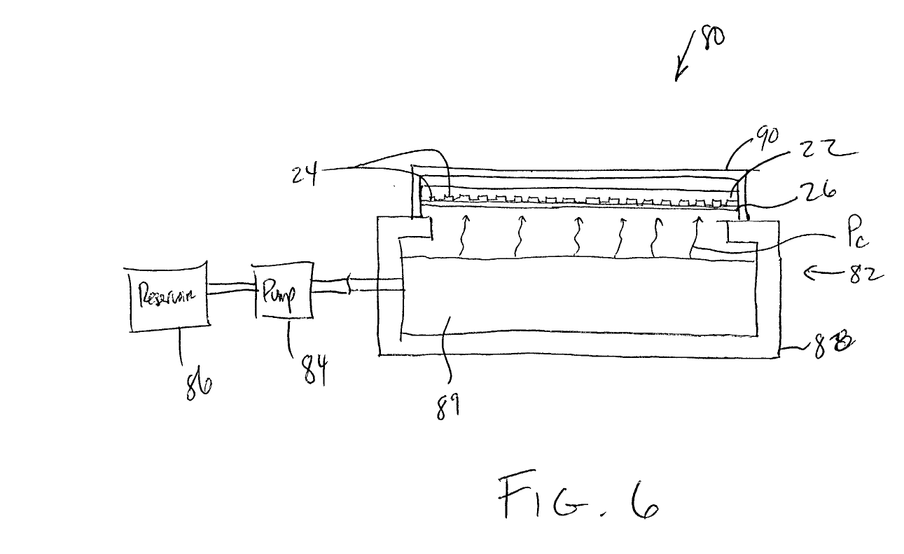

FIG. 6 is a simplified illustration of another embodiment of the present invention. In this embodiment, a process system 80 includes a chamber 82, pump 84 and fluid reservoir 86. Chamber 82 includes a fluid bath 88 and a substrate holder 90, which can be operably coupled together to be completely pressurized. Accordingly, substrate 22 can be placed and secured onto substrate holder 90 in an inverted position, such that recesses 24 are facing down and opposed to fluid bath 88. Foil 26 can be tightened over substrate 22 before the metallization process begins. Pump 84 can be used to draw a fluid 89, such as deionized water, from reservoir 86 to fill fluid bath 88. Fluid 89 fills fluid bath 88 causing a chamber pressure Pc to impinge on foil 26. Chamber pressure Pc causes foil 26 to be forced into recesses 24 to fill recesses 24. The amount of pressure Pc forced upon foil 26 and substrate surface 46 can vary depending on, for example, the type of foil 26 being used, the depth of recesses 24 and the desired rate at which the processes is to proceed. For example, chamber pressure Pc impinging on substrate 22 can range from between about 20 psig and 300 psug. Typically, recesses 24 are filled until the foil material filling each recess 24 is substantially co-planer with substrate surface 46. Once the operation is complete, chamber 82 can be pumped down and substrate 22 can be removed.

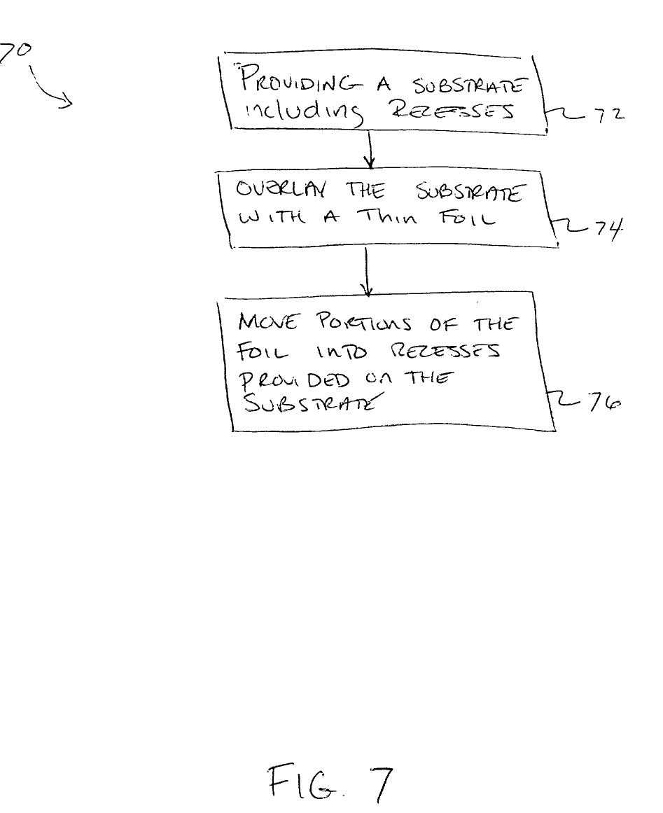

FIG. 7 is a flow diagram of a process 70 in accordance with the present invention. In describing process 70, reference is made to the embodiments of FIGS. 1-6. In action 72, substrate 22 is provided. Substrate 22 includes a plurality of recesses 24 and/or holes defined on substrate surface 46. In action 74, substrate 22 and thus, substrate surface 46 including recesses 24 are overlaid with a resistive material. In one embodiment, the resistive material includes foil 26, for example, a metal foil, which may be made of gold, aluminum, nickel, cobalt, silver, tungsten, titanium, tantalum, copper and alloys thereof.

Once foil 26 is in position, in action 74 a part to all of foil 26 is moved into the plurality of recesses 24. Movement of foil 26 into recesses 24 can be accomplished using pressurizing device 20, which is used to subject substrate surface 46 to a pressure, which forces foil 26 into recesses 24. In one embodiment, pressurizing device includes a roller assembly 40, which includes a roller 42 made to roll over substrate surface 46 using actuator 44. Roller 42, which can be heated to facilitate the movement of foil 26, applies a rolling pressure to surface 46 causing foil 46 to enter each recess 24. In another embodiment, pressurizing device 20 can include a pressure applicator 50. Pressure applicator 50 causes a fluid, such as a gas or liquid, to impinge on substrate surface 46 causing foil 26 to enter recesses 24. In yet another embodiment, substrate 22 having foil 26 overlaying substrate surface 46 can be placed in process chamber 62 and subjected to chamber pressure Pc. Chamber pressure Pc impinges on substrate surface 46 and is substantially high enough to cause foil 46 to enter recesses 24 on substrate 22.

While the principles of the invention have been described in connection with certain embodiments, it is to be understood that this description is not a limitation on the scope of the invention. Persons skilled in the art will recognize that changes may be made in form and detail without departing from the scope of the invention. Thus, the invention is limited only by the following claims.

What is claimed is:

1. A method of metallization comprising:
providing a substrate including a first surface defining a plurality of recesses;
overlaying a resistive foil on said first surface; and
subjecting said substrate to a pressure to cause said resistive foil to enter said plurality of recesses.

2. The method of claim 1, wherein said resistive foil comprises a metal taken from the group consisting of gold, aluminum, nickel, cobalt, silver, tungsten, titanium, tantalum, copper and alloys thereof.

3. The method of claim 1, wherein said subjecting said substrate to a pressure comprises applying a mechanical force over an area of said substrate.

4. The method of claim 1, wherein said subjecting said substrate to a pressure comprises causing a roller to contact said foil overlaid on said substrate.

5. The method of claim 4, wherein said roller is heated to a temperature between about 100° C. and about 800° C.

6. The method of claim 1, wherein said subjecting said substrate to a pressure comprises impinging said foil overlaid on said substrate with a fluid stream.

7. The method of claim 1, wherein said subjecting said substrate to a pressure comprises:
placing said substrate in a process chamber; and thereafter
substantially increasing a chamber pressure.

8. The method of claim 1, wherein said substrate is positioned proximate to a heated susceptor.

9. The method of claim 1, wherein said recesses provide electrical contact areas, vias, interlevel metallization, and interconnection routing.

10. A system for metallizing a substrate comprising:
a process chamber defining a cavity configured to receive a substrate having a plurality of recesses and including a foil disposed thereon; and
a pressurizing device for applying a pressure to said substrate to cause said foil to move into each of said plurality of recesses.

11. The system of claim 10, wherein said foil comprises a metal foil taken from the group consisting of gold, aluminum, nickel, cobalt, silver, tungsten, titanium, tantalum, copper and alloys thereof.

12. The system of claim 10, wherein said pressurizing device comprises a roller assembly including a roller coupled to an actuator for causing said roller to move over an area of said substrate to apply a mechanical force thereon.

13. The system of claim 12, wherein said roller is heated to a temperature between about 100° C. and about 800° C.

14. The system of claim 10, wherein said pressurizing device comprises a pressure applicator including a nozzle, wherein a stream of pressurized fluid can emanate from said nozzle to impinge on said substrate and apply a force over an area of said substrate to force said foil into each of said recesses.

15. The system of claim 14, wherein said pressurized fluid is a gas or a liquid.

16. The system of claim 10, wherein said pressuring device causes said process chamber to be filled with a fluid to increase a chamber pressure, said increased chamber pressure forcing said foil into said recesses.
